(19) United States
(12) Patent Application Publication
(10) Pub. No.: US 2012/0122278 A1
(43) Pub. Date: May 17, 2012

(54) Method Of Manufacturing Semiconductor Package Board

(75) Inventors: Kwan Ho LEE, Seoul (KR); Yong Hui Joo, Gyunggi-do (KR); Tae Hyun KIM, Seoul (KR); Seog Moon CHOI, Seoul (KR)

(73) Assignee: SAMSUNG ELECTRO-MECHANICS CO., LTD., Gyunggi-do (KR)

(21) Appl. No.: 13/007,530

(22) Filed: Jan. 14, 2011

(30) Foreign Application Priority Data
Nov. 11, 2010 (KR) 10-2010-0112281

(51) Int. Cl. H01L 21/98

(52) U.S. Cl. 438/107; 257/E21.705

(57) ABSTRACT

Disclosed herein is a method of method of manufacturing a semiconductor package board, including: providing a substrate including a connection part formed on one side thereof, the connection part being provided thereon with a solder layer; disposing a conductive heat generator equipped with current wiring on the solder layer; applying current to the current wiring and thus heating the solder layer to attach a semiconductor chip to the connection part; and removing the current wiring from the conductive heat generator. The method is advantageous in that the semiconductor chip is attached to the substrate by applying current to the current wiring of the conductive heat generator to locally heat only the solder layer, thus reducing thermal stress and preventing the deformation of the substrate.

### CROSS REFERENCE TO RELATED APPLICATION

This application claims the benefit of Korean Patent Application No. 10-2010-0112281, filed Nov. 11, 2010, entitled “Method of Manufacturing the package board”, which is hereby incorporated by reference in its entirety into this application.

### BACKGROUND OF THE INVENTION

1. Technical Field

The present invention relates to a method of manufacturing a semiconductor package board.

2. Description of the Related Art

Recently, in the electronic industry, in order to make electronic appliances small and thin, technologies for mounting electronic components using a semiconductor package board on which electronic components can be highly densified, highly defined, and highly integrated have been required. As electronic components are becoming highly densified, highly defined, and highly integrated, the stability of a semiconductor package board is required, and, particularly, the reliability of the junction between a semiconductor chip and a board is very important.

Hereinafter, a conventional method of manufacturing a semiconductor package board will be described with reference to FIGS. 1 to 5.

First, as shown in FIG. 1, a double-sided copper clad laminate 11 including an insulation layer 12 provided on both sides thereof with copper foil 13 is provided. Subsequently, as shown in FIG. 2, via holes 14 and copper plating layers 15 are formed, and then circuit layers 16 are formed on both sides of the double-sided copper clad laminate 11 by patterning.

Subsequently, as shown in FIG. 3, a solder resist 17 having an opening for exposing a connection pad is formed, and surface treatment layers 18, such as nickel/gold plating layers, are formed on both sides of the exposed connection pad.

Subsequently, as shown in FIG. 4, a solder ball 19 is formed on the upper side of the connection pad. Finally, as shown in FIG. 5, a semiconductor chip 20 is disposed on the solder balls 19, and is then put into a reflow oven 30 and then heated to attach the connecting terminal of the semiconductor chip 20 to the connection pad of a substrate 10.

In the reflow process, both the semiconductor chip 20 and the substrate 10 are put into the reflow oven 30, and are then heated to the melting point of the solder ball 19 or above for 20˜30 minutes. In this case, since the substrate 10 has been entirely heated, thermal stress occurs due to the difference in thermal expansion coefficient between the substrate 10, the solder ball 19 and the semiconductor chip 20. Further, when the substrate 10 is heated and then cooled again, the upper and lower portions of the substrate 10 become nonsymmetric due to the expansion and contraction of the substrate 10, so that the substrate 10 deforms, with the result that the semiconductor chip 20 deviates from the original attached position or the thickness of the solder ball 19 becomes nonuniform, thereby deteriorating attachment reliability.

### SUMMARY OF THE INVENTION

Accordingly, the present invention has been devised to solve the above-mentioned problems, and the present invention intends to reduce thermal stress and improve the attachment reliability between a semiconductor chip and a substrate by disposing a conductive heat generator equipped with current wiring on a solder layer, applying current to the current wiring to locally heat only the solder layer and then mounting a semiconductor chip on the connection part of a substrate.

An aspect of the present invention provides a method of manufacturing a semiconductor package board, including: providing a substrate including a connection part formed on one side thereof, the connection part being provided thereon with a solder layer; disposing a conductive heat generator equipped with current wiring on the solder layer; applying current to the current wiring and thus heating the solder layer to attach a semiconductor chip to the connection part; and removing the current wiring from the conductive heat generator.

Here, the method may further include: disposing an auxiliary solder layer for covering the conductive heat generator before the attaching of the semiconductor chip to the connection part.

Further, the method may further include: cooling the other side of the substrate in the attaching of the semiconductor chip to the connection part.

Further, the other side of the substrate may be cooled while room temperature is being maintained.

Further, in the method, the substrate may include a plurality of leads around the connection part in the providing of the substrate, and the semiconductor chip includes a plurality of bonding pads formed thereon in the attaching of the semiconductor chip to the connection part. The method may further include: connecting the plurality of bonding pads with the plurality of leads using metal wires such that they correspond to each other after the attaching of the semiconductor chip to the connection part.

Further, in the method, the substrate may include a plurality of connection parts in the providing of the substrate; a plurality of conductive heat generators connected by current wiring may be disposed on the solder layer such that they correspond to the plurality of connection parts in the disposing of the conductive heat generator; and the plurality of the semiconductor chips may be attached to the plurality of the connection parts in the attaching of the semiconductor chip to the connection part.

Further, the connection part may be provided with one or more connection pads electrically connected with the solder layer, and the semiconductor chip may be provided with one or more connecting terminals electrically connected with the solder layer.

Further, the conductive heat generator may be a carbon sheet.

Further, the conductive heat generator may have a size corresponding to that of the solder layer.

Further, the conductive heat generator may have a mesh structure.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 5 are sectional views sequentially showing a conventional method of manufacturing a semiconductor package board;

FIGS. 6 to 12 are sectional views and plan views sequentially showing a method of manufacturing a semiconductor package board according to the present invention;

FIG. 13 is a sectional view showing a semiconductor package board to which a semiconductor chip is attached by a wire; and

FIGS. 14 and 15 are sectional views sequentially showing a process of attaching a plurality of semiconductor chips to a substrate.

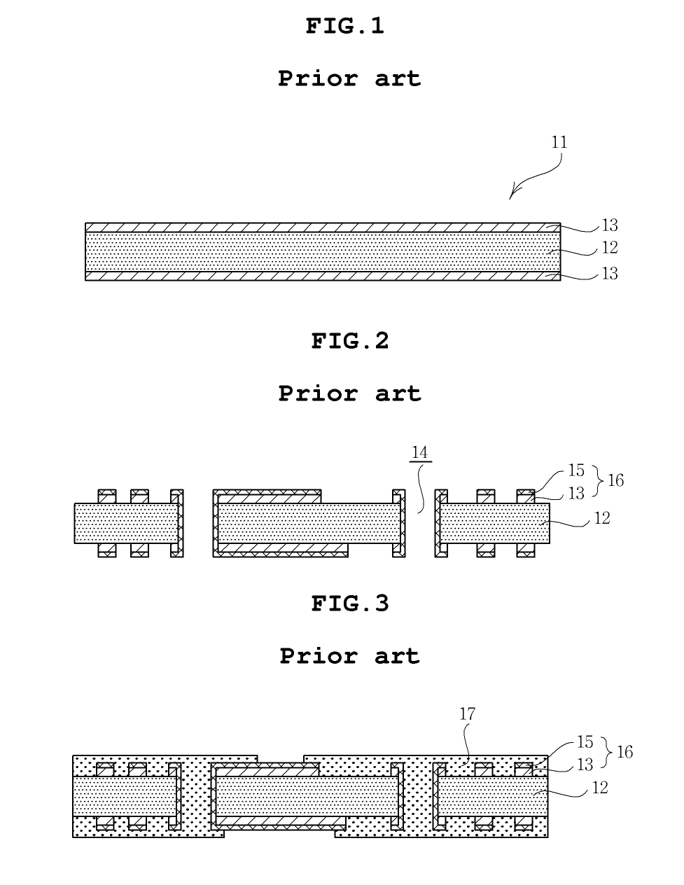

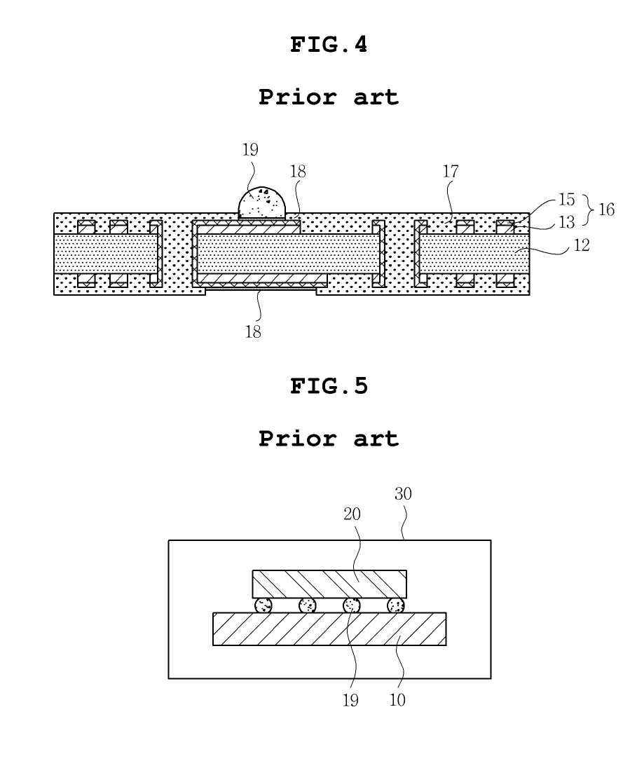

### DESCRIPTION OF THE PREFERRED EMBODIMENTS

The objects, features and advantages of the present invention will be more clearly understood from the following detailed description of preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

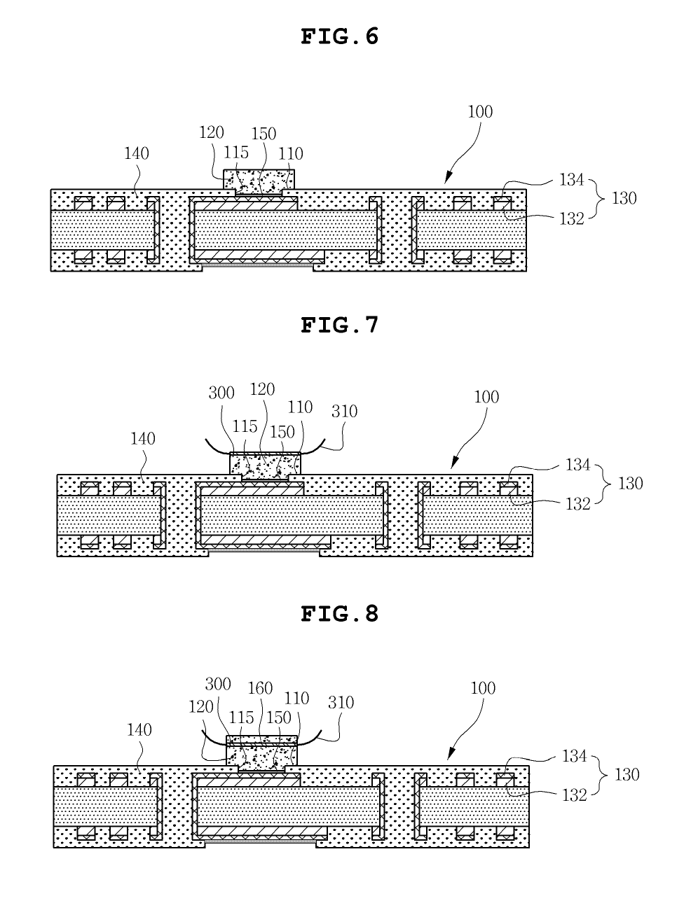

FIGS. 6 to 12 are sectional views and plan views sequentially showing a process of manufacturing a semiconductor package board according to the present invention

First, as shown in FIG. 6, a substrate 100 including a connection part 110 on which a solider layer 120 is disposed is provided. Concretely, a process of providing the substrate 100 includes: providing a substrate 100 including a connection part 110 formed at one side thereof and a circuit layer 130 formed therein; forming a solder resist layer 140 on the substrate 100; forming an opening in the solder resist layer 140 to expose a connection pad 115 of the connection part 110; and forming a solder layer 120.

The substrate 100 is a circuit board in which one or more circuit layers including a connector part 110 are formed on an insulation layer, and, preferably, may be a printed circuit board (PCB). The printed circuit board (PCB), which serves to electrically interconnect the mounted components using an inner circuit layer formed in an insulation plate such as a phenol resin plate or an epoxy resin plate, to supply powder to the components and to mechanically fix the components, includes a single-side PCB in which a circuit layer 130 is formed on one side of an insulation layer and a double-side PCB in which circuit layers 130 are formed on both sides thereof. FIG. 6 shows a multilayered printed circuit board including one insulation layer and two circuit layers 130. However, the present invention is limited thereto, and a multilayered printed circuit board including two or more circuit layers may be applied.

The connection part 110 is provided thereon with a solder layer 120 by a subsequent process, and the substrate 100 is mounted thereon with a semiconductor chip 200 or an external component by the solder layer 120.

In this case, the connection part 110 may include one or more connection pads 115. The connection pad 115 serves to connect the semiconductor chip mounted on the substrate 100 with the circuit layer 130 formed in the substrate 100 through the solder layer 120. The connection pad 115 is made of a conductive metal, such as copper, gold, silver, nickel or the like. The connection pad 115 is generally made of copper.

The solder resist layer 140 serves to protect the outermost circuit, and is provided with an opening for exposing the connection pad 115 of the connection part 110. The solder resist layer 140 may be made of an insulating material, such as ink, encapsulant or the like, but the present invention is not limited thereto.

A surface treatment layer 150 may be additionally formed on the connection pad 115 of the connection part 110 exposed through the opening of the solder resist layer 140. The surface treatment layer 150 may be formed by electro gold plating, immersion gold plating, immersion silver plating, electroless nickel immersion gold plating (ENIG), direct immersion plating (DIP), hot air solder levelling (HASL) or the like.

The solder layer 120 serves to attach an external component such as a semiconductor chip 200 to the connection part 110 of the substrate 100, and is formed by printing solder paste on the exposed connection part 110 using a screen printing tool such as a squeegee or the like. The solder layer may be made of tin/lead (Sn/Pb), tin/silver/copper (Sn/Ag/Cu), tin/silver (Sn/Ag), tin/copper (Sn/Cu), tin/bismuth (Sn/Bi), tin/zinc/bismuth (Sn/Zn/Bi), tin/silver/bismuth (Sn/Ag/Bi) or the like.

As shown in FIG. 7, a conductive heat generator 300 equipped with current wiring 310 is disposed on the solder layer 120. The conductive heat generator 300 is provided at both ends thereof with the current wiring 310, and heats the solder layer 120 by applying current to the current wiring 310. This conductive heat generator 300 may be made of a conductor such as silver, copper, nichrome or the like. When the solder layer 120 is heated to its melting point or above, the semiconductor chip 200 is attached to the connection part 110 of the substrate 100 by the solder layer 120, and simultaneously the conductive heat generator 300 is immersed into the solder layer 120.

Here, as shown in FIG. 8, an auxiliary solder layer 160 for covering the conductive heat generator 300 may be disposed on the conductive heat generator 300. When the auxiliary solder layer 160 is disposed on the conductive heat generator 300, the conductive heat generator 300 is immersed into the solder layer 120, and thus the solder layer 120 can be rapidly heated to its melting point or above. The auxiliary solder layer 160 is formed using a squeegee or the like.

In this case, the conductive heat generator 300 may be a carbon sheet. This carbon sheet is made of a mixture of a carbon nanomaterial, such as carbon nanotube (CNT), graphene or the like, and expanded graphite. Since the carbon sheet has excellent electric conductivity and thermal conductivity, it can efficiently heat the solder layer 120 for a short period of time, thus reducing process time.

Further, since the carbon sheet has excellent strength and elasticity, the mechanical properties of the solder layer 120 can be improved by immersing the carbon sheet into the solder layer 120. Further, since the carbon sheet has a low thermal expansion coefficient, when this carbon sheet is immersed into the solder layer 120, the thermal expansion coefficient of the solder layer 120 can be reduced, thus decreasing the difference in thermal expansion coefficient between the substrate 100, the solder layer 120 and the semiconductor chip 200.

It is preferred that the size of the conductive heat generator 300 correspond to that of the solder layer 120. When the size of the conductive heat generator is smaller than that of the solder layer, there is a problem in that a large amount of power is consumed in order to heat the solder layer 120 to its melting point or above and heating time becomes long. Conversely, when the size of the conductive heat generator is larger than that of the solder layer, there is a problem in that it is difficult to locally heat only the solder layer 120.

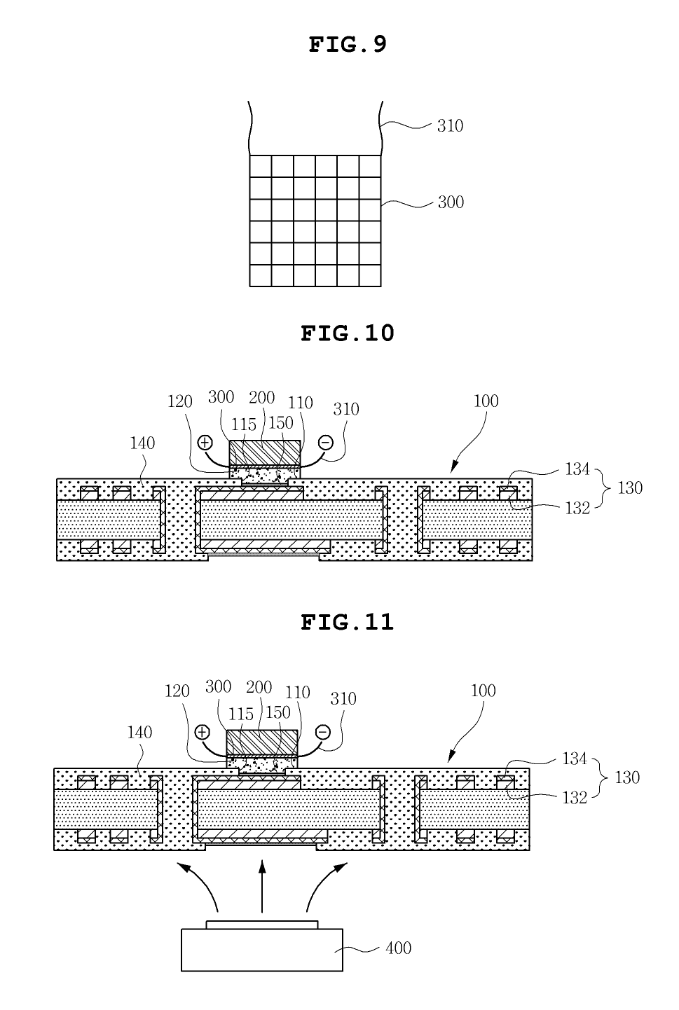

Further, as shown in FIG. 9, the conductive heat generator 300 may have a mesh structure. When the conductive heat generator 300 has a mesh structure, heat is uniformly transferred to the solder layer 120, and thus the solder layer 120 can be effectively heated. Further, in this case, since the conductive heat generator 300 is uniformly immersed into the solder layer 120 per unit area, the mechanical properties of the solder layer 120 can be effectively improved.

As shown in FIG. 10, the solder layer 120 is heated by applying current to the current wiring 310 of the conductive heat generator 300, thus attaching the semiconductor chip 200 to the connection part 110 of the substrate 100. When current flows in the conductive heat generator 300, heat is generated, and the solder layer 120 is heated to a melting point or more using this heat. In this case, there is an advantage in that the heating temperature can be precisely controlled by controlling the amount of current applied to the current wiring 310. That is, only the solder layer 120 is locally heated by applying current to the current wiring 310 of the conductive heat generator 300, thus preventing the substrate 100 from being deformed and reducing the thermal stress resulting from the differences in thermal expansion coefficients.

The semiconductor chip 200 attached to the substrate 100 may include one or more connecting terminals, and the connection part 110 of the substrate 100 is provided with one or more connection pads 115. Since the semiconductor chip 200 is attached to the substrate 100 by the solder layer 120, the semiconductor chip 200 can be electrically connected with the circuit layer formed in the substrate 100.

In this case, as shown in FIG. 11, when the semiconductor chip 200 is attached to the substrate 100 by heating the solder layer 120, a process of cooling the other side of the substrate 100 may be conducted. When the other side of the substrate 100 is cooled by a cooler 400, the heat emitted from the conductive heat generator 300 is not applied to the substrate 100 excluding the solder layer 120, thus completely preventing the substrate 100 from being deformed by the heat.

The other side of the substrate 100 may be cooled while room temperature is being maintained, because the substrate 100 is slightly influenced by the temperature of other components at the room temperature.

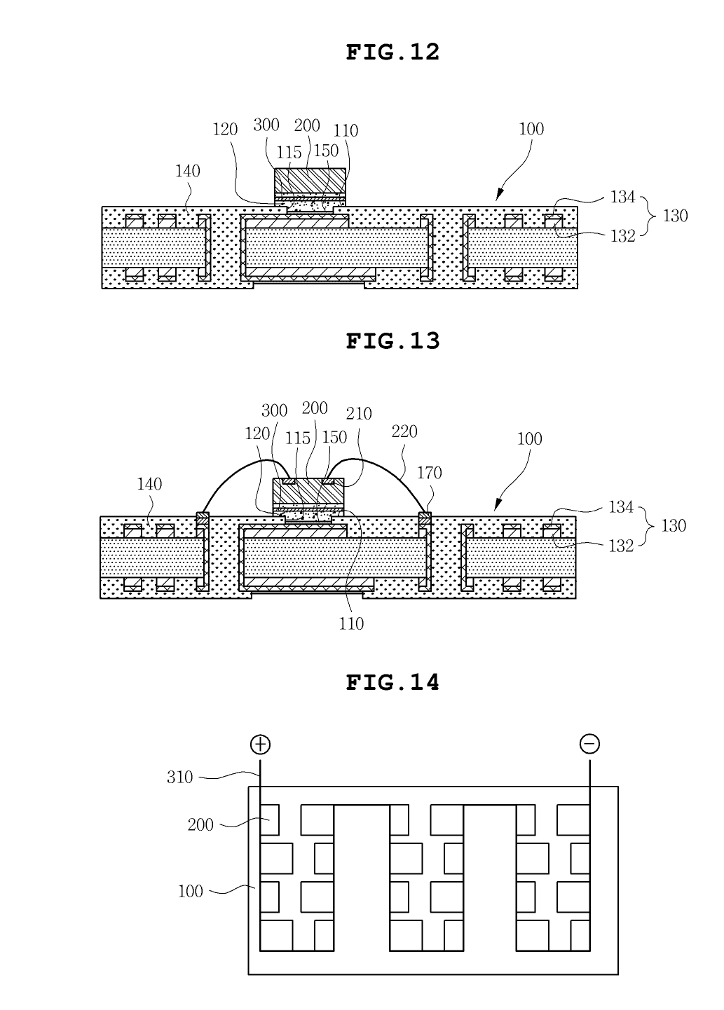

Subsequently, as shown in FIG. 12, the current wire 310 is removed from the conductive heat generator 300.

In the method of manufacturing a semiconductor package board according to the present invention, the attachment of the semiconductor chip 200 is not limited as above, and may be conducted using a wire 220. In the case of attaching the semiconductor 200 to the substrate 100 using the wire 220, as shown in FIG. 13, the substrate further include a plurality of leads 170 around the connection part 110. The plurality of leads is electrically connected to the circuit layer 130 of the substrate 100.

The conductive heat generator 300 equipped with the current wiring is disposed on the solder layer 120, and then the solder layer 120 is heated by applying current to the current wiring 310, thus attaching the semiconductor chip 200 to the connection part 110 of the substrate 100.

In the case of attaching the semiconductor 200 to the substrate 100 using the wire 220, a plurality of bonding pads 210 is provided on the semiconductor chip 200, and then the plurality of bonding pads 210 are connected with the plurality of leads 170 of the substrate 100 by wires 220 such that they correspond to each other. The wire 220 is generally made of gold (Au) or aluminum (Al). In this case, the semiconductor chip 200 is not electrically connected to the circuit layer 130 formed in the substrate 100 using only the wires 220 connected the leads 170, but may be electrically connected to the circuit layer 130 formed in the substrate 100 using only the connection pad 115 formed in the connection part 110.

Subsequently, the current wire 310 is removed from the conductive heat generator 300. The process of removing the current wiring 310 may be conducted before the leads 170 are attached to the substrate 100 by the wires 220.

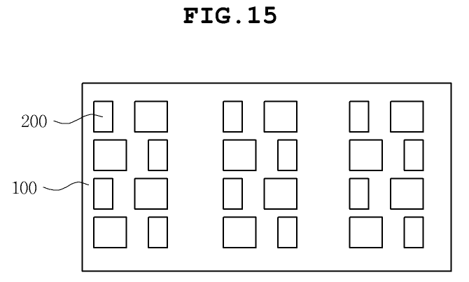

Further, as shown in FIGS. 14 and 15, a plurality of semiconductor chips 200 may be simultaneously attached to the substrate 100. As shown in FIG. 14, the substrate 100 is provided with a plurality of connection parts 110, and a plurality of conductive heat generators 300 connected by current wiring 310 is disposed on the solder layer 120 such that they correspond to the plurality of connection parts 110.

The plurality of semiconductor chips 200 are attached to the connection parts of the substrate 100 by applying current to the both ends of the current wiring 310, and, as shown in FIG. 15, the current wiring 310 is removed from the plurality of semiconductor chips 200. As in the conventional reflow process, the plurality of semiconductor chips 200 can be simultaneously attached to the connection parts 110 of the substrate 100.

According to the method of manufacturing a semiconductor package board of the present invention, a conductive heat generator equipped with current wiring is disposed on the solder layer formed on the connection part of a substrate, and then current is applied to the current wiring to heat the solder layer, thus attaching a semiconductor chip to the connection part. Therefore, since only the solder layer of the substrate is heated, thermal stress is reduced, and the deformation of the substrate is prevented, thereby improving the attachment reliability between the semiconductor chip and the substrate.

Further, the other side of the substrate is cooled, so that heat is not transferred to the semiconductor chip and the substrate excluding the connection part, thus improving the reliability of attachment between the semiconductor chip and the substrate.

Further, the connection part of the substrate is provided with one or more connection pads, and the semiconductor chip attached to the substrate includes one or more connecting terminals. Since the semiconductor chip is attached to the substrate by the solder layer, the semiconductor chip can be electrically connected with the circuit layer formed in the substrate.

Further, since the conductive heat generator is made of a carbon sheet and this carbon sheet has excellent thermal conductivity, the solder layer can be heated to a melting point or more for a short period of time, and the mechanical properties of the solder layer can be improved by immersing the carbon sheet into the solder layer at the time of attaching the semiconductor chip to the substrate.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Simple modifications, additions and substitutions of the present invention belong to the scope of the present invention, and the specific scope of the present invention will be clearly defined by the appended claims.

What is claimed is:

1. A method of manufacturing a semiconductor package board, comprising:
providing a substrate including a connection part formed on one side thereof, the connection part being provided thereon with a solder layer;
disposing a conductive heat generator equipped with current wiring on the solder layer;
applying current to the current wiring and thus heating the solder layer to attach a semiconductor chip to the connection part; and
removing the current wiring from the conductive heat generator.

2. The method according to claim 1, further comprising:
disposing an auxiliary solder layer for covering the conductive heat generator before the attaching of the semiconductor chip to the connection part.

3. The method according to claim 1, further comprising:
cooling the other side of the substrate in the attaching of the semiconductor chip to the connection part.

4. The method according to claim 3, wherein the other side of the substrate is cooled while room temperature is being maintained.

5. The method according to claim 1, wherein the substrate includes a plurality of leads around the connection part in the providing of the substrate;
wherein the semiconductor chip includes a plurality of bonding pads formed thereon in the attaching of the semiconductor chip to the connection part; and
wherein the method further comprises: connecting the plurality of bonding pads with the plurality of leads using metal wires such that they correspond to each other after the attaching of the semiconductor chip to the connection part.

6. The method according to claim 1, wherein the substrate includes a plurality of connection parts in the providing of the substrate;
wherein a plurality of conductive heat generators connected by current wiring is disposed on the solder layer such that they correspond to the plurality of connection parts in the disposing of the conductive heat generator; and
wherein the plurality of the semiconductor chips are attached to the plurality of the connection parts in the attaching of the semiconductor chip to the connection part.

7. The method according to claim 1, wherein the connection part is provided with one or more connection pads electrically connected with the solder layer, and the semiconductor chip is provided with one or more connecting terminals electrically connected with the solder layer.

8. The method according to claim 1, wherein the conductive heat generator is a carbon sheet.

9. The method according to claim 1, wherein the conductive heat generator has a size corresponding to that of the solder layer.

10. The method according to claim 1, wherein the conductive heat generator has a mesh structure.
